(19) United States
(12) Patent Application Publication
(10) Pub. No.: US 2018/0062015 A1
(43) Pub. Date: Mar. 1, 2018

(54) INTELLIGENT SOLAR PHOTOVOLTAIC MODULE CIRCUIT AND CONTROL/PROTECTION METHOD THEREFOR

(71) Applicant: Suzhou Talesun Solar Technologies, Co., Ltd., Suzhou, Jiangsu (CN)

(72) Inventors: Zhichun NI, Suzhou, Jiangsu (CN); Leizhen HU, Suzhou, Jiangsu (CN); Mingjiang XU, Suzhou, Jiangsu (CN); Zhixiang XU, Suzhou, Jiangsu (CN)

(73) Assignee: Suzhou Talesun Solar Technologies, Co., Ltd., Suzhou, Jiangsu (CN)

(21) Appl. No.: 15/553,461

(22) PCT Filed: Dec. 29, 2015
(86) PCT No.: PCT/CN2015/099482

§ 371 Date: Aug. 24, 2017

(30) Foreign Application Priority Data
Mar. 9, 2015 (CN) 201510100986.4

(51) Int. Cl. H01L 31/05; G05F 1/67; H01L 31/02; H02J 3/38

(52) U.S. Cl. CPC H01L 31/05; H02J 3/385; H01L 31/02021; G05F 1/67

(57) ABSTRACT

Provided are an intelligent solar photovoltaic module circuit and a control method therefor. The circuit includes: multiple photovoltaic strings connected in series, where each of the photovoltaic strings includes an intelligent photovoltaic module unit and a maximum power point tracking (MPPT) functional module connected in series with the intelligent photovoltaic module unit; a central processing unit (CPU) memory module configured to receive and analyze a state of the intelligent photovoltaic module unit; and a control module electrically connected with the CPU memory module and configured to control a MPPT function, where each of the photovoltaic strings is connected with a switch transistor configured to short-circuit the intelligent photovoltaic module unit or disconnect the photovoltaic string from other photovoltaic strings, and the switch transistor is controlled by the control module.

This application claims the priority to Chinese Patent Application No. 201510100986.4, titled “INTELLIGENT SOLAR PHOTOVOLTAIC MODULE CIRCUIT AND CONTROL/PROTECTION METHOD THEREFOR” and filed with the State Intellectual Property Office of the People's Republic of China on Mar. 9, 2015, which is incorporated herein by reference in its entirety.

### TECHNICAL FIELD

The present disclosure relates to the field of photovoltaic device, and in particular to a control/protection method for an intelligent solar photovoltaic module circuit.

### BACKGROUND

Generally, in a photovoltaic power station, there is always a MPPT conversation circuit at the direct current (DC) side of a grid-connected inverter to solve the problem of mismatch. A conventional centralized grid-connected photovoltaic inverter and a string type grid-connected photovoltaic inverter each includes the MPPT conversion circuit.

In recent years, to solve the problem of mismatch between solar photovoltaic modules, an alternating current (AC) module and an intelligent module appear. Main structures of an AC module and an intelligent module, together with a conventional solar photovoltaic module for comparison, are shown in FIG. 1.

The AC module is high in cost for its complicated circuit structure and more electronic components. And the intelligent module can achieve the objective of mismatch optimization and communication.

The structure of a normal intelligent module is shown in FIG. 2. By adjusting a duty ratio of a switch S, the objective of adjusting an output voltage to achieve a maximum power point tracking can be realized. CPU and memory communicates with the outside by means of RF. When the intelligent module breaks down and needs to be disconnected from the entire string, remote control is performed to disconnect T1 and T2, thus the intelligent module is isolated. In this solution, the entire string may be disconnected when a single solar photovoltaic module is disconnected, thus the output of the entire string is affected. Referring to FIG. 3, it is assumed that a middle solar photovoltaic module in FIG. 3 requires to be disconnected from the string due to a fault, the method is applied by controlling actions of switches T3 and T4 to make an output of the middle solar photovoltaic module be disconnected, thus isolating the middle solar photovoltaic module from the string, that is, switches in the red ring in FIG. 3 are disconnected, so there is no current in the whole circuit, which may result in no output power in the entire string of the solar photovoltaic module.

### SUMMARY

The objective of the present disclosure is to provide an intelligent solar photovoltaic module circuit which not only has no influence on other solar photovoltaic modules in a string but also has existing functions of power optimization and communication when cutting off an output of a single solar photovoltaic module in a photovoltaic power station with intelligent modules.

In order to attain the foregoing objective, the technical solutions provided in the present disclosure are described as follows. An intelligent solar photovoltaic module circuit includes:

multiple photovoltaic strings connected in series, where each of the photovoltaic strings includes an intelligent photovoltaic module unit and a MPPT functional module connected in series with the intelligent photovoltaic module unit;

a CPU memory module configured to receive and analyze a state of the intelligent photovoltaic module unit; and

a control module electrically connected with the CPU memory module and configured to control a MPPT function, where

each of the photovoltaic strings is connected with a switch transistor configured to short-circuit the intelligent photovoltaic module unit or disconnect the photovoltaic string from other photovoltaic strings, and the switch transistor is controlled by the control module.

Preferably, each of the photovoltaic strings includes one switch transistor; an anode of the switch transistor is connected with an anode of the intelligent photovoltaic module unit, a cathode of the switch transistor is connected with a cathode of the photovoltaic module, and a control electrode of the switch transistor is connected with an output end of the control module; and the photovoltaic module unit in any one of the photovoltaic strings is short-circuited in a case that the switch transistor in the photovoltaic string is turned on.

Preferably, each MPPT functional module includes: an adjusting switch, where a cathode of the adjusting switch is connected with an anode of the photovoltaic module unit and the adjusting switch is configured to adjust a duty ratio; a first diode and a second diode, where anodes of the first diode and the second diode are connected with a cathode of the photovoltaic module unit; an induction coil connected between a cathode of the first diode and a cathode of the second diode; and a capacitor, where one end of the capacitor is connected between the induction coil and the cathode of the second diode and the other end of the capacitor is connected with the cathode of the photovoltaic module unit, and the cathode of the first diode is connected with an anode of an adjusting switch. The switch transistor includes a first switch transistor and a second switch transistor, an anode of the first switch transistor is connected with a connecting end at which the induction coil and the capacitor are connected, and a cathode of the first switch transistor is connected with the cathode of the second diode; a cathode of the second switch transistor is connected with the cathode of the photovoltaic module unit, and an anode of the second switch transistor is connected with the anode of the second diode; and the photovoltaic module unit in any one of the photovoltaic strings is disconnected in a case that the first switch transistor and the second diode in the photovoltaic string are turned off.

It is also provided a control/protection method for the intelligent solar photovoltaic module circuit according to the disclosure, the control/protection method includes:

detecting, by the CPU memory module, whether a fault appears or maintenance is required in the intelligent photovoltaic module unit;

outputting, by the CPU memory module, a signal to the control module in a case that the fault appears or the maintenance is required; and

outputting, by the control module, a signal to the switch transistor to short-circuit the intelligent photovoltaic module unit or disconnect the photovoltaic string from other photovoltaic strings.

Advantageous effects of the present disclosure are described as follows. Firstly, an MPPT structure is simplified, thereby reducing the application of power electronic devices, improving the efficiency and decreasing the cost; secondly, even if a single solar photovoltaic module is disconnected due to a fault, the output of the entire string is not affected, thereby greatly increasing the utilization rate of photoelectricity.

### BRIEF DESCRIPTION OF THE DRAWINGS

FIG. 1 is a structural diagram illustrating a conventional photovoltaic module, an AC photovoltaic module and an intelligent photovoltaic module in the conventional art;

FIG. 2 is a structural diagram illustrating a photovoltaic module unit in the conventional art;

FIG. 3 is a structural diagram illustrating a photovoltaic string in the conventional art;

FIG. 4 is a diagram illustrating an IV characteristic of a non-linear electric component and a linear electric component;

FIG. 5 is a structural diagram illustrating a photovoltaic module unit in a first embodiment of the present disclosure;

FIG. 6 is a structural diagram illustrating a photovoltaic string in a first embodiment of the present disclosure;

FIG. 7 is a structural diagram illustrating a photovoltaic module unit in a second embodiment of the present disclosure; and

FIG. 8 is a structural diagram illustrating a photovoltaic string in a second embodiment of the present disclosure.

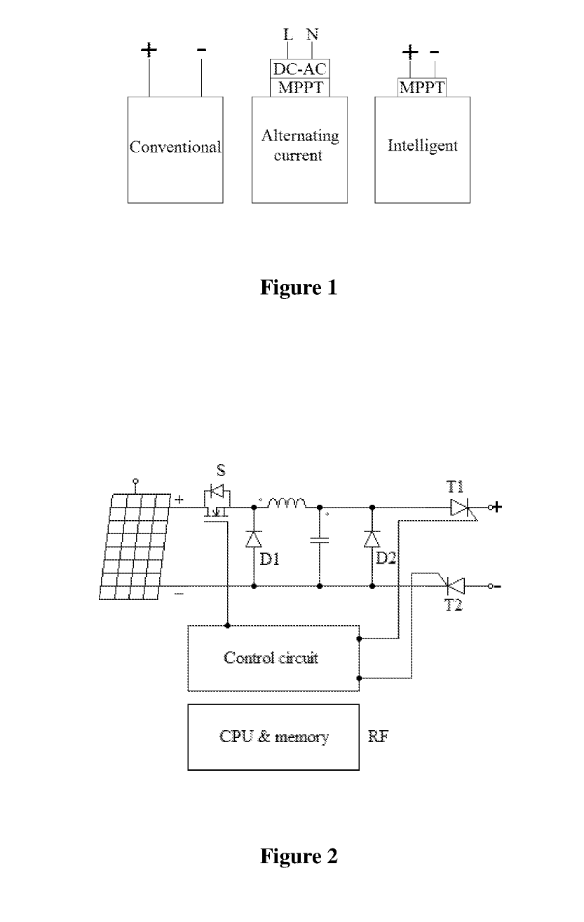

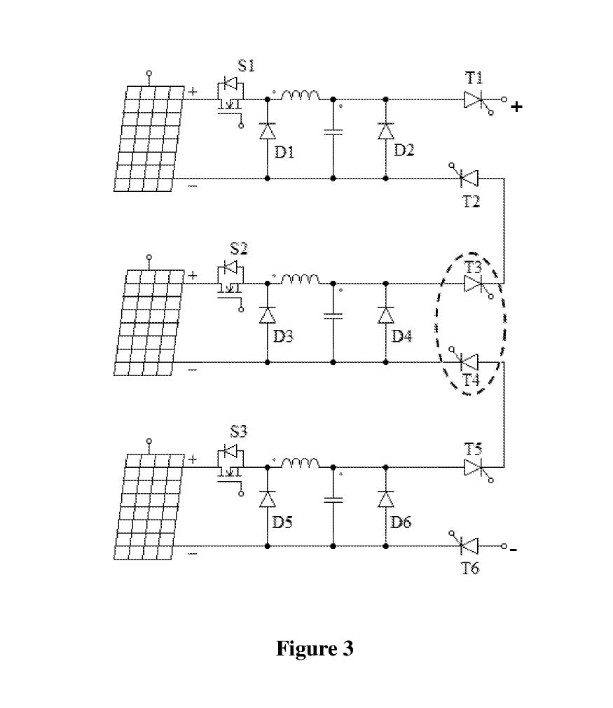

### DETAILED DESCRIPTION OF THE EMBODIMENTS

The present disclosure will be described in detail as follows in conjunction with the embodiments shown in accompany drawings.

### First Embodiment

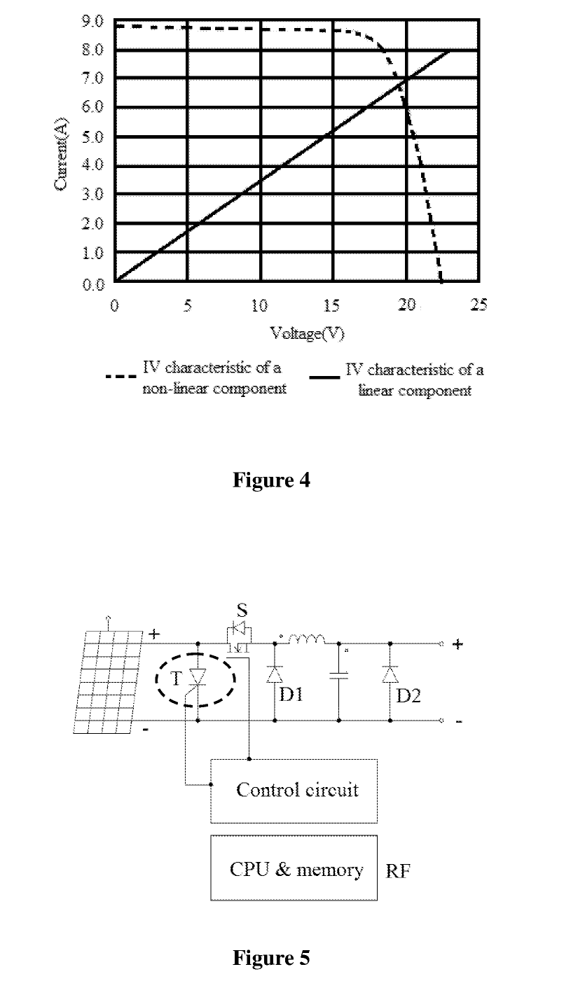

As shown in FIG. 4, the IV characteristic of a solar photovoltaic module is not like that of a conventional power source because the solar photovoltaic module is a non-linear component. The IV curve of a solar photovoltaic module can be approximately considered as a curve composed by a curve vertical to the ordinate axis (the current axis) and a curve vertical to the abscissa axis (the voltage axis). When an operating point of a load is on the curve vertical to the ordinate axis, a solar photovoltaic module may be approximately considered as a current source; when an operating point of a load is on the curve vertical to the abscissa axis, the solar photovoltaic module may be approximately considered as a voltage source. So it can be regarded that a solar photovoltaic module has both characteristic of a current source and characteristic of a voltage source. That is, a solar photovoltaic module can be short circuited like a current source. Thus an intelligent solar photovoltaic module circuit is designed by making use of this characteristic. By canceling the existing two switches T1 and T2 in FIG. 2 and adding a switch transistor T between the output anode and the output cathode of a photovoltaic module unit, a intelligent solar photovoltaic module circuit is formed as shown in FIG. 5. The intelligent solar photovoltaic module circuit includes multiple photovoltaic strings connected in series, each of the photovoltaic strings includes an intelligent photovoltaic module unit and a maximum power point tracking (MPPT) functional module connected in series with the intelligent photovoltaic module unit. The intelligent solar photovoltaic module circuit further includes a CPU memory module configured to receive and analyze a state of the intelligent photovoltaic module unit; and a control module electrically connected with the CPU memory module and configured to control a MPPT function. Each of the photovoltaic strings is connected with a switch transistor configured to short-circuit the photovoltaic module unit or disconnect the photovoltaic string from other photovoltaic strings, and the switch transistor is controlled by the control module. The photovoltaic string includes one switch transistor; an anode of the switch transistor is connected with an anode of the photovoltaic module unit, a cathode of the switch transistor is connected with a cathode of the photovoltaic module unit, and a control electrode of the switch transistor is connected with an output end of the control module.

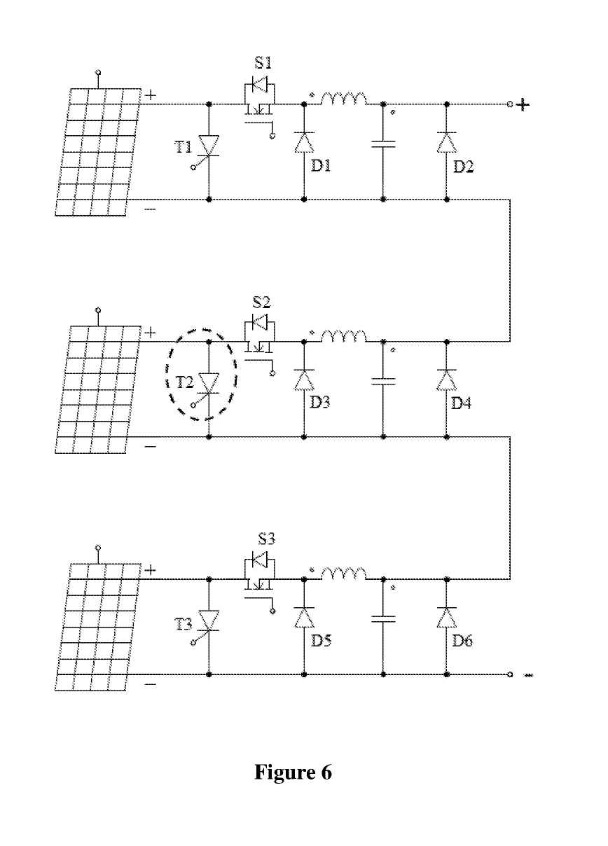

When a photovoltaic module unit has a fault or requires for maintenance, whether a photovoltaic module unit is short-circuited between the anode and the cathode of the photovoltaic module unit is controlled by controlling a switch transistor T. When the switch transistor T is turned on, the photovoltaic module unit is short-circuited between the anode and the cathode of the photovoltaic module unit, and there is no output to the outside by the photovoltaic module unit. Referring to FIG. 6, it is assumed that a middle photovoltaic module unit requires to be disconnected from the photovoltaic string due to a fault, just by controlling switch T2 to make the photovoltaic module unit be short-circuited, the middle photovoltaic module unit can be isolated from the entire string without affecting the operating state of the entire string, thus improving the utilization rate of energy.

### Second Embodiment

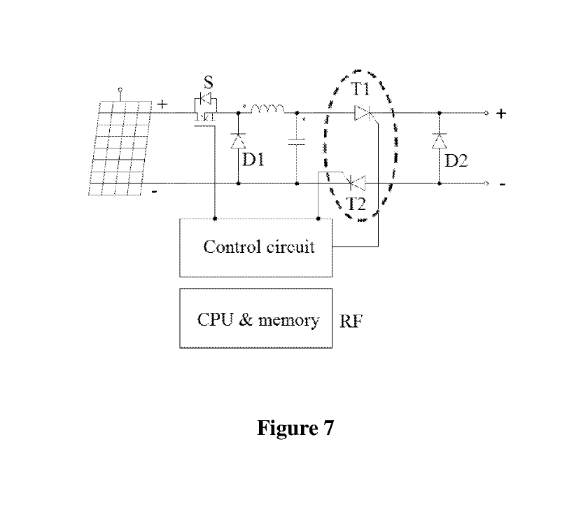

As shown in FIG. 7, an intelligent solar photovoltaic module circuit in this embodiment includes multiple photovoltaic strings connected in series, each of the photovoltaic strings includes an intelligent photovoltaic module unit and a MPPT functional module connected in series with the intelligent photovoltaic module unit. The intelligent solar photovoltaic module circuit further includes a CPU memory module configured to receive and analyze a state of the intelligent photovoltaic module unit; and a control module electrically connected with the CPU memory module and configured to control a MPPT function. Each of the photovoltaic strings is connected with a switch transistor configured to short-circuit the intelligent photovoltaic module unit or disconnect the photovoltaic string from other photovoltaic strings, and the switch transistor is controlled by the control module. Each MPPT functional module includes: an adjusting switch, where a cathode of the adjusting switch is connected with an anode of the photovoltaic module unit and the adjusting switch is configured to adjust a duty ratio; a first diode and a second diode, where anodes of the first diode and the second diode are connected with a cathode of the photovoltaic module unit; an induction coil connected between a cathode of the first diode and a cathode of the second diode; and a capacitor, where one end of the capacitor is connected between the induction coil and the cathode of the second diode and the other end of the capacitor is connected with the cathode of the photovoltaic module unit, and the cathode of the first diode is connected with an anode of an adjusting switch. The switch transistor includes a first switch transistor and a second switch transistor. An anode of the first switch transistor is connected with a connecting end at which the induction coil and the capacitor are connected, and a cathode of the first switch transistor is connected with the cathode of the second diode. A cathode of the second switch transistor is connected with the cathode of the photovoltaic module unit, and an anode of the second switch transistor is connected with the anode of the second diode.

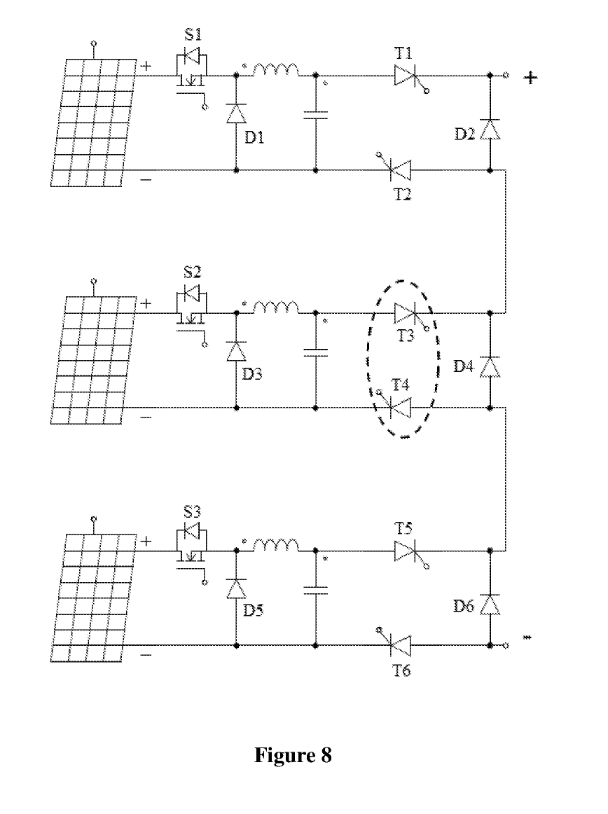

By controlling the first switch transistor and the second switch transistor to be turned off, a single photovoltaic module unit can be isolated from the entire string without affecting the operating state of the entire string. Referring to FIG. 8, it is assumed that the middle photovoltaic module unit requires to be isolated, then just by turning off T3 and T4, the middle solar photovoltaic module can be eliminated from the entire string and the output of the string are not affected.

A control/protection method for the intelligent solar photovoltaic module circuit according to the above two embodiments includes: detecting, by the CPU memory module, whether a fault appears or maintenance is required in the intelligent photovoltaic module unit; outputting, by the CPU memory module, a signal to the control module in a case that the fault appears or the maintenance is required; and outputting, by the control module, a signal to the switch transistor to short-circuit the intelligent photovoltaic module unit or disconnect the photovoltaic string from other photovoltaic strings.

The foregoing embodiments are only to describe technical concepts and features of the disclosure. Those skilled in the art may understand content of the disclosure and perform implementation based on the above embodiments. The embodiments are not meant to limit the protection scope of the disclosure. All equivalent alternations or modifications made according to the spirit of the disclosure should fall within the protection scope of the disclosure.

1. An intelligent solar photovoltaic module circuit, comprising:
a plurality of photovoltaic strings connected in series, wherein each of the photovoltaic strings comprises an intelligent photovoltaic module unit and a maximum power point tracking (MPPT) functional module connected in series with the intelligent photovoltaic module unit;
a central processing unit (CPU) memory module configured to receive and analyze a state of the intelligent photovoltaic module unit; and
a control module electrically connected with the CPU memory module and configured to control a MPPT function, wherein
each of the photovoltaic strings is connected with a switch transistor configured to short-circuit the intelligent photovoltaic module unit or disconnect the photovoltaic string from other photovoltaic strings, and the switch transistor is controlled by the control module.

2. The intelligent solar photovoltaic module circuit according to claim 1, wherein
each of the photovoltaic strings comprises one switch transistor;
an anode of the switch transistor is connected with an anode of the intelligent photovoltaic module unit, a cathode of the switch transistor is connected with a cathode of the photovoltaic module, and a control electrode of the switch transistor is connected with an output end of the control module; and
the photovoltaic module unit in any one of the photovoltaic strings is short-circuited in a case that the switch transistor in the photovoltaic string is turned on.

3. The intelligent solar photovoltaic module circuit according to claim 1, wherein
each MPPT functional module comprises:
an adjusting switch, wherein a cathode of the adjusting switch is connected with an anode of the photovoltaic module unit and the adjusting switch is configured to adjust a duty ratio,
a first diode and a second diode, wherein anodes of the first diode and the second diode are connected with a cathode of the photovoltaic module unit,
an induction coil connected between a cathode of the first diode and a cathode of the second diode, and
a capacitor, wherein one end of the capacitor is connected between the induction coil and the cathode of the second diode and the other end of the capacitor is connected with the cathode of the photovoltaic module unit, and the cathode of the first diode is connected with an anode of an adjusting switch; and
the switch transistor comprises a first switch transistor and a second switch transistor, wherein
an anode of the first switch transistor is connected with a connecting end at which the induction coil and the capacitor are connected, and a cathode of the first switch transistor is connected with the cathode of the second diode,
a cathode of the second switch transistor is connected with the cathode of the photovoltaic module unit, and an anode of the second switch transistor is connected with the anode of the second diode, and
the photovoltaic module unit in any one of the photovoltaic strings is disconnected in a case that the first switch transistor and the second diode in the photovoltaic string are turned off.

4. A control method for an intelligent solar photovoltaic module circuit, comprising:
detecting, by a central processing unit (CPU) memory module, whether a fault appears or maintenance is required in an intelligent photovoltaic module unit;
outputting, by the CPU memory module, a signal to a control module in a case that the fault appears or the maintenance is required; and
outputting, by the control module, a signal to a switch transistor to short-circuit the intelligent photovoltaic module unit or disconnect a photovoltaic string from other photovoltaic strings.
